(19) United States
(12) Patent Application Publication
(10) Pub. No.: US 2020/0212287 A1
(43) Pub. Date: Jul. 2, 2020

(54) DEVICE FOR DAMPING PLATE-SHAPED MEMBER

(71) Applicant: HONDA MOTOR CO., LTD., Tokyo (JP)

(72) Inventors: Shunji Suzuki, Wako-shi (JP); Toshizumi Yamaguchi, Wako-shi (JP)

(21) Appl. No.: 16/705,440

(22) Filed: Dec. 6, 2019

(30) Foreign Application Priority Data
Dec. 27, 2018 (JP) 2018-244725

(51) Int. Cl. H01L 41/113; H01L 41/04

(52) U.S. Cl. CPC H01L 41/1132; H01L 41/042; H01L 41/1138

(57) ABSTRACT

A device for damping a plate-shaped member includes a piezoelectric element actuator, a piezoelectric element sensor, and a control circuit which carries out feedback control of operation of the piezoelectric element actuator based on an output voltage from the piezoelectric element sensor so as to suppress vibration of the plate-shaped member. The control circuit includes a low pass filter which reduces a high frequency gain of a voltage inputted into the piezoelectric element actuator in a region in which a vibrational frequency of the plate-shaped member is a predetermined value or greater. Therefore, amplification of vibration in such a frequency region can be suppressed. Accordingly, a feedback gain is increased by a control objective frequency, so that vibration can be suppressed, and noise accompanying the vibration can be reduced.

### BACKGROUND OF THE INVENTION

### Field of the Invention

The present invention relates to a device for damping a plate-shaped member, comprising a piezoelectric element actuator and a piezoelectric element sensor that are disposed on a surface of a plate-shaped member, and a control circuit that carries out feedback control of operation of the piezoelectric element actuator based on an output voltage from the piezoelectric element sensor so as to suppress vibration of the plate-shaped member.

### Description of the Related Art

Japanese Patent Application Laid-open No. 2014-206257 has made known an arrangement in which a piezoelectric element sensor (piezo element for detection) and a piezoelectric element actuator (piezo element for damping) are fixed to a peripheral wall face of a damper of an automobile suspension system, the piezoelectric element sensor detects as a voltage signal its own deformation accompanying vibration of the damper, and the piezoelectric element actuator is driven by amplifying the voltage signal by means of an amplifier circuit, to thus expand and contract the damper and suppress the vibration.

A piezoelectric element actuator and a piezoelectric element sensor are fixed to a surface of a plate-shaped member, the input to the piezoelectric element actuator is fed back from a circuit based on a voltage signal outputted by the piezoelectric element sensor, which detects strain generated in the surface of the plate in response to film surface vibration of the plate-shaped member, the vibration of the plate-shaped member is thus suppressed, and the accompanying noise can be improved.

In order for the piezoelectric element actuator to exhibit a damping effect it is necessary to set the feedback gain to be larger than 0 dB, but as explained in details in the ‘DESCRIPTION OF THE PREFERRED EMBODIMENT’ section, if the feedback gain is set to be larger than 0 dB in order to obtain a larger amount of damping, there is the problem that the vibration is amplified and noise is generated in a frequency region in which the phase lag of the output voltage of the piezoelectric element sensor exceeds 180°.

### SUMMARY OF THE INVENTION

The present invention has been accomplished in light of the above circumstances, and it is an object, in a device for damping a plate-shaped member, the device being equipped with a piezoelectric element actuator, a piezoelectric element sensor, and a control circuit, to make it possible to prevent amplification of vibration in a region in which the vibrational frequency is a predetermined value or greater, and to increase the feedback gain, thereby suppressing the vibration and reducing noise accompanying the vibration.

In order to achieve the object, according to a first aspect of the present invention, there is provided a device for damping a plate-shaped member, comprising a piezoelectric element actuator and a piezoelectric element sensor that are disposed on a surface of a plate-shaped member, and a control circuit that carries out feedback control of operation of the piezoelectric element actuator based on an output voltage from the piezoelectric element sensor so as to suppress vibration of the plate-shaped member, wherein the control circuit comprises a low pass filter that removes a high frequency component of an input voltage to the piezoelectric element actuator in a region in which a vibrational frequency of the plate-shaped member is a predetermined value or greater.

In accordance with the first aspect, since the device for damping a plate-shaped member includes the piezoelectric element actuator and the piezoelectric element sensor, which are disposed on a surface of the plate-shaped member, and the control circuit, which carries out feedback control of the operation of the piezoelectric element actuator based on an output voltage from the piezoelectric element sensor so as to suppress vibration of the plate-shaped member, it is possible to suppress the vibration of the plate-shaped member and improve noise accompanying the vibration.

Since the control circuit includes the low pass filter, which reduces the high frequency gain of the voltage inputted into the piezoelectric element actuator, amplification of vibration in a region in which the vibrational frequency is a predetermined value or greater can be prevented, the feedback gain can be increased, the vibration can be suppressed, and noise accompanying the vibration can be reduced.

According to a second aspect of the present invention, in addition to the first aspect, the piezoelectric element actuator forms at least part of the low pass filter.

In accordance with the second aspect, since the piezoelectric element actuator has a role as a capacitor component within the low pass filter, compared with a case in which a capacitor for forming the low pass filter is provided separately, it is possible to reduce the number of components, decrease the size, lighten the weight, and cut the cost.

According to a third aspect of the present invention, in addition to the second aspect, the low pass filter comprises the piezoelectric element actuator and a resistor that is arranged immediately in front of and connected to the piezoelectric element actuator within the control circuit.

In accordance with the third aspect, since the low pass filter is formed from the piezoelectric element actuator and the resistor, which is arranged immediately in front of and connected to the piezoelectric element actuator within the control circuit, it becomes possible to form the low pass filter from the resistor and the piezoelectric element actuator.

According to a fourth aspect of the present invention, in addition to the third aspect, the resistor and the piezoelectric element actuator are connected in series or in parallel.

In accordance with the fourth aspect, since the resistor and the piezoelectric element actuator are connected in series or in parallel, when the resistor and the piezoelectric element actuator are connected in series, the capacitance of the capacitor decreases, and the resistance value can be increased, and when the resistor and the piezoelectric element actuator are connected in parallel, the capacitance of the capacitor increases, and the resistance value can be decreased, thereby increasing the degree of freedom in setting the resistance value.

The above and other objects, characteristics and advantages of the present invention will be clear from detailed descriptions of the preferred embodiment which will be provided below while referring to the attached drawings.

### BRIEF DESCRIPTION OF THE DRAWINGS

FIG. 1 is a view showing a plate-shaped member equipped with a sensor and an actuator.

FIG. 2 is a view showing the overall arrangement of a damping device.

FIG. 3 is a control block diagram of the damping device.

FIGS. 4A and 4B are Bode plots of a loop transfer function of a control system of the damping device.

FIG. 5 is a circuit diagram of the damping device.

### DESCRIPTION OF THE PREFERRED EMBODIMENT

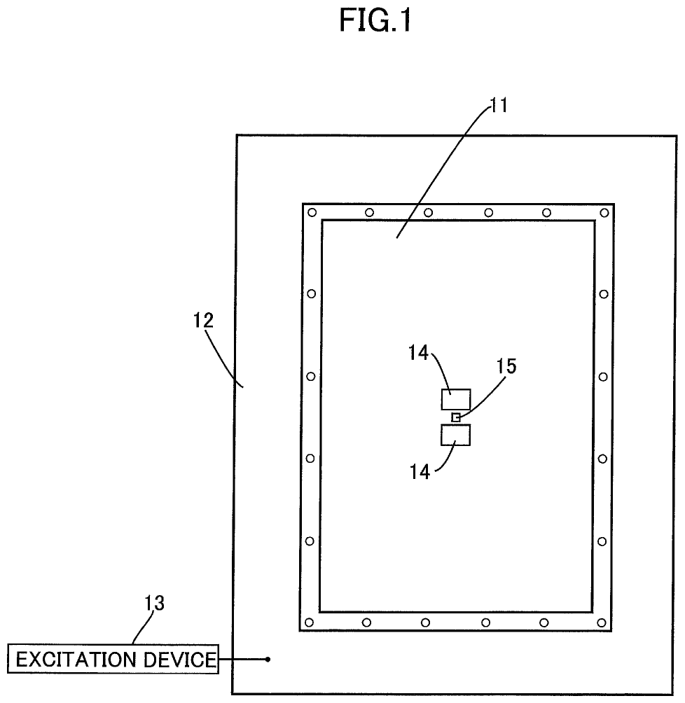

An embodiment of the present invention is explained below based on FIGS. 1 to 5.

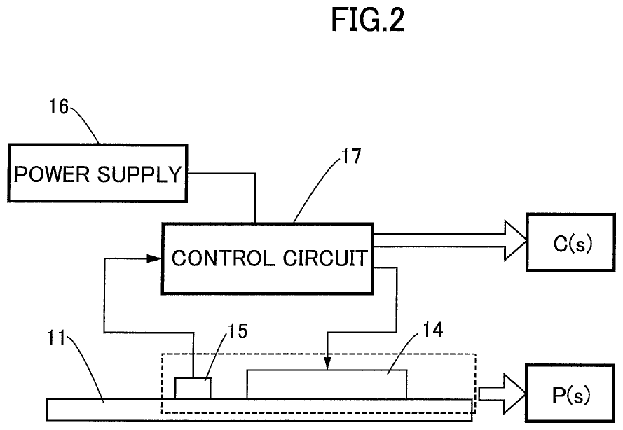

As shown in FIG. 1 and FIG. 2, a plate-shaped member 11 to which a damping device according to a preferred embodiment of the present invention is applied is formed from a rectangular panel made of a carbon fiber-reinforced plastic, and a metal frame 12 supporting an outer peripheral part of the plate-shaped member 11 via an elastic material having a sufficiently lower modulus of elasticity than that of the metal frame is connected to an excitation device 13 and is excited at various frequencies. The damping device for damping the plate-shaped member 11, which is vibrated by the excitation device 13, includes two rectangular sheet-shaped piezoelectric element actuators 14, one rectangular sheet-shaped piezoelectric element sensor 15, a power supply 16, and a control circuit 17 that controls the operation of the piezoelectric element actuator 14 based on an output of the piezoelectric element sensor 15.

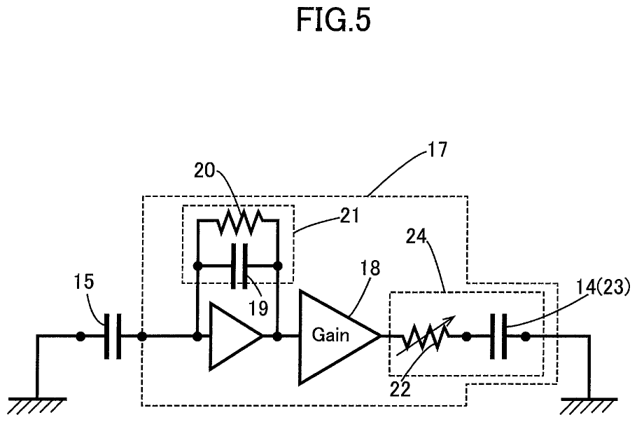

As shown in FIG. 5, the control circuit 17, which is disposed between the piezoelectric element sensor 15 and the piezoelectric element actuator 14, includes an amplifier 18 that is formed from an operational amplifier, a high pass filter 21 that is formed from a capacitor 19 and a resistor 20 connected in parallel, and a low pass filter 24 that is formed from a resistor 22 and a capacitor 23 connected in series. The piezoelectric element actuator 14, which can function as a capacitor, is used also as the capacitor 23 of the low pass filter 24.

When the plate-shaped member 11 is disposed in for example a horizontal state, one piezoelectric element sensor 15 is fixed to a central part of one surface (e.g. an upper face) of the plate-shaped member 11 by adhesion, and two piezoelectric element actuators 14 are fixed by adhesion to the upper face of the plate-shaped member 11 so as to sandwich said one piezoelectric element sensor 15 from opposite sides.

Since the piezoelectric element sensor 15 is fixed to the upper face of the plate-shaped member 11, which is made to undergo film surface vibration in the up-down direction by the excitation device 13, when the plate-shaped member 11 is curved so as to protrude upward, the piezoelectric element sensor 15 is stretched and outputs a negative voltage, and on the other hand when the plate-shaped member 11 is curved so as to protrude downward, the piezoelectric element sensor 15 is constricted and outputs a positive voltage.

Since the piezoelectric element actuator 14 is fixed to the upper face of the plate-shaped member 11, if a positive voltage is applied to the piezoelectric element actuator 14 to thus cause it to constrict in the in-plane direction when the plate-shaped member 11 is curved so as to protrude upward, a damping force that suppresses the curving of the plate-shaped member 11 is generated, and on the other hand if a negative voltage is applied to the piezoelectric element actuator 14 to thus cause it to stretch in the in-plane direction when the plate-shaped member 11 is curved so as to protrude downward, a damping force that suppresses the curving of the plate-shaped member 11 is generated.

Therefore, due to the control circuit 17 carrying out feedback control of stretching and constriction of the piezoelectric element actuator 14 so that strain of the plate-shaped member 11 detected by the piezoelectric element sensor 15, which detects strain of the plate surface due to bending vibration of a plate, converges to zero, it is possible to damp the vibration of the plate-shaped member 11.

In a primary resonance mode or a tertiary resonance mode in which the plate-shaped member 11 undergoes particularly large vibration, the central part of the plate-shaped member 11 becomes a vibrational antinode and the amplitude becomes the largest, and placing the piezoelectric element sensor 15 at that position enables strain of the plate-shaped member 11 to be reliably detected and vibration amplified by resonance to be damped effectively.

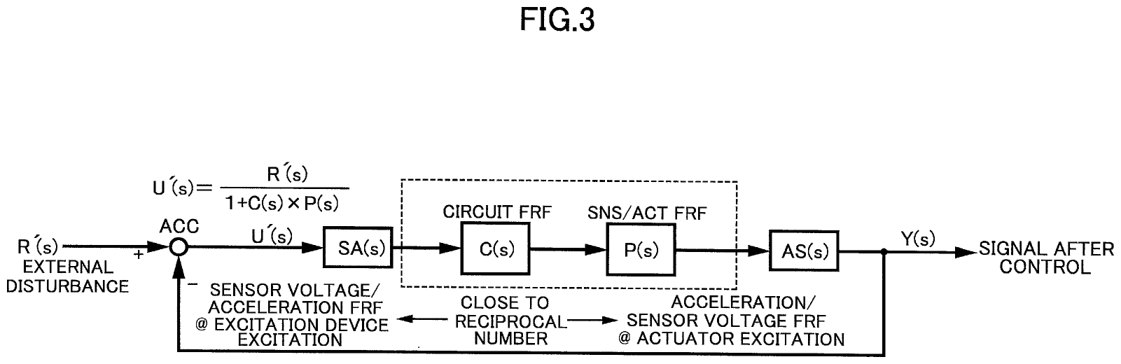

In a block diagram of the control system shown in FIG. 3, P(s) [V/V] is a transfer function (FRF) of the voltage outputted by the piezoelectric element sensor 15 with respect to the voltage applied to the piezoelectric element actuator 14, C(s) [V/V] is a transfer function of the voltage inputted into the piezoelectric element actuator 14 with respect to the voltage outputted by the piezoelectric element sensor 15, SA(s) [V/m/s²] is a sensor voltage/acceleration transfer function when excitation is carried out by the excitation device 13, and AS(s) [m/s²N] is an acceleration/sensor voltage transfer function when excitation is carried out by the piezoelectric element actuator 14.

P(s), which is denoted by the piezoelectric element sensor/piezoelectric element actuator (SNS/ACT) transfer function, is determined by the layout, which includes the dimensions, shapes, and positional relationship of the piezoelectric element actuator 14 and the piezoelectric element sensor 15. C(s), which is the transfer function of the control circuit 17, defines the amount of amplification of the control circuit 17. Since SA(s) and As(s) are in a substantially reciprocal relationship, a loop transfer function that determines the damping performance of the control system is expressed as [C(s)×P(s)].

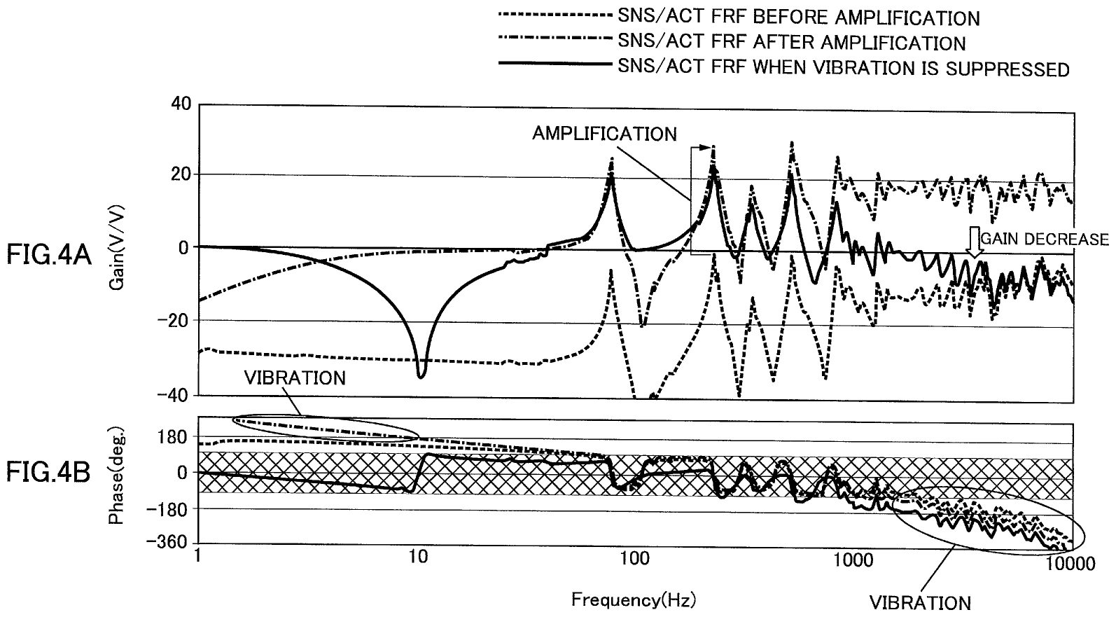

FIGS. 4A and 4B are Bode plots of the loop transfer function [C(s)×P(s)]; FIG. 4A is a gain plot with respect to the vibrational frequency of the plate-shaped member 11, and FIG. 4B is a phase plot with respect to the vibrational frequency of the plate-shaped member 11. The broken line represents the characteristics P(s), the chain line represents the characteristics after the amplifier 18 of the control circuit 17, and the solid line represents the characteristics after suppression of vibration in a frequency region of 100 Hz or below is carried out and amplification and suppression of high frequency vibration are carried out by the control circuit 17.

Due to the effect of the high pass filter, which is explained later, in a frequency region of 100 Hz or below, decrease in the gain and advancement of the phase occur as shown by the chain line.

In order for the piezoelectric element actuator 14 to exhibit an effective damping function, it is necessary for the gain to be larger than 0 dB and for the phase shift to be in a region of −90° to 90°, but since the characteristics prior to amplification shown by the broken line are such that the gain is less than 0 dB, it is necessary, by increasing the gain by the amplifier 18 of the control circuit 17 so that it is greater than 0 dB, to obtain a state shown by the chain line. However, when the feedback gain is increased and the gain becomes larger than 0 dB in order to reduce the vibration, the phase shift deviates greatly from a region of −90° to 90° and exceeds 180° in a frequency region of 100 Hz or below, the vibration is amplified in this frequency region, and noise is generated.

The reason why the phase shift exceeds 180° is as follows. It is unavoidable that the output of the piezoelectric element sensor 15 will include a direct current component due to the influence of temperature change or static deformation; if the vibration component of the output of the piezoelectric element sensor 15 is amplified in a state in which the direct current component is included, the amplifier 18 attains the limit of amplification, and it is therefore necessary to remove the direct current component using the high pass filter 21. However, if the high pass filter 21 is used, not only does the gain decrease but the phase also advances, and if two or more high pass filters 21 are used, the phase shift exceeds 180°.

Furthermore, since the piezoelectric element actuator 14 and the piezoelectric element sensor 15 are disposed across a predetermined distance, it is unavoidable that a certain time lag will occur before strain generated in the piezoelectric element actuator 14 is transferred to the piezoelectric element sensor 15 and is detected. Since the vibrational period is long in a low frequency region, the influence of the time lag on the phase is relatively small, but since in a high frequency region the vibrational period is short, the influence of the time lag on the phase is relatively large, the phase shift deviates greatly from the −90° to 90° region and exceeds −180° in a high frequency region of 1000 Hz or greater, the vibration is amplified in this high frequency region, and noise is generated, which is a problem.

In order to decrease the distance between the piezoelectric element actuator 14 and the piezoelectric element sensor 15, the piezoelectric element actuator 14 and the piezoelectric element sensor 15 may be disposed so as to overlap each other, but by so doing the piezoelectric element sensor 15 preferentially detects strain of the plate-shaped member 11 caused by the piezoelectric element actuator 14, and it becomes difficult to detect strain of the plate-shaped member 11 caused by an external disturbance, thus giving rise to the problem that the damping performance is degraded.

The present invention solves, among oscillatory phenomena in the very low frequency region and the high frequency region described above, the oscillatory phenomenon in the high frequency region by means of the low pass filter 24 of the control circuit 17.

That is, in the Bode plots of FIGS. 4A and 4B, due to the piezoelectric element actuator 14 and the piezoelectric element sensor 15 being disposed across a predetermined distance, there is the problem that the phase lag exceeds −180° and the vibration is amplified in a high frequency region, but the high frequency gain is reduced to less than 0 dB by means of the low pass filter 24 of the control circuit 17. As a result, it is possible, by suppressing the amplification of vibration in the high frequency region, to increase the feedback gain, thus suppressing the vibration and improving the noise accompanying it.

Moreover, since the piezoelectric element actuator 14 for damping the plate-shaped member 11 is utilized as the capacitor 23 of the low pass filter 24, compared with a case in which a capacitor is provided separately, it is possible to decrease the number of components of the damping device, reduce the size, lighten the weight, and cut the cost.

An embodiment of the present invention is explained above, but the present invention may be modified in a variety of ways as long as the modifications do not depart from the gist of the present invention.

For example, in the embodiment the piezoelectric element actuator 14 and the piezoelectric element sensor 15 are fixed on the surface of the plate-shaped member 11 on the same side, but the piezoelectric element actuator 14 may be fixed to one surface of the plate-shaped member 11, and the piezoelectric element sensor 15 may be fixed to the other surface of the plate-shaped member 11. In addition, since the polarity of the output voltage of the piezoelectric element sensor 15 changes according to which side it is fixed to, it is necessary to process the polarity of the output voltage of the piezoelectric element sensor 15 by means of the control circuit 17 according to the surface to which the piezoelectric element sensor 15 is fixed.

Furthermore, in the embodiment the resistor 22 and the capacitor 23 (piezoelectric element actuator 14) are connected in series, but they may be connected in parallel. Since the cutoff frequency of the low pass filter 24 is expressed as ½ πRC (product of resistance value and capacitance), when the capacitance of the capacitor 23 (piezoelectric element actuator 14) is determined, it is necessary to adjust the cutoff frequency by means of the resistance value. In this case, if the resistance value is very low, it is necessary to use a resistor having temperature stability, and the cost might increase, and if it is very high, the cost might also increase. From the viewpoint of reducing the cost, changing the piezoelectric element actuator 14 from parallel connection to series connection reduces the capacitance of the capacitor, thus enabling the resistance value to be increased, and changing the piezoelectric element actuator 14 from series connection to parallel connection increases the capacitance of the capacitor, thus enabling the resistance value to be decreased, therefore increasing the degree of freedom in setting the resistance value.

Moreover, the number of piezoelectric element actuators 11 and the number of piezoelectric element sensors 15 are not limited to those in the embodiment, and any number may be employed.

Furthermore, the material of the plate-shaped member 11 is not limited to the carbon fiber-reinforced plastic plate of the embodiment, and another type of fiber-reinforced resin plate or any metal plate such as a steel plate or an aluminum plate may be used.

Moreover, in the embodiment the piezoelectric element actuator 14 and the piezoelectric element sensor 15 are fixed to the plate-shaped member 11 by adhesion, but they may be fixed by a method other than adhesion and may also be mounted detachably.

What is claimed is:

1. A device for damping a plate-shaped member, comprising
a piezoelectric element actuator and a piezoelectric element sensor that are disposed on a surface of a plate-shaped member, and
a control circuit that carries out feedback control of operation of the piezoelectric element actuator based on an output voltage from the piezoelectric element sensor so as to suppress vibration of the plate-shaped member,
wherein the control circuit comprises a low pass filter that removes a high frequency component of an input voltage to the piezoelectric element actuator in a region in which a vibrational frequency of the plate-shaped member is a predetermined value or greater.

2. The device for damping a plate-shaped member according to claim 1, wherein the piezoelectric element actuator forms at least part of the low pass filter.

3. The device for damping a plate-shaped member according to claim 2, wherein the low pass filter comprises the piezoelectric element actuator and a resistor that is arranged immediately in front of and connected to the piezoelectric element actuator within the control circuit.

4. The device for damping a plate-shaped member according to claim 3, wherein the resistor and the piezoelectric element actuator are connected in series or in parallel.
